(19) United States
(12) Patent Application Publication
(10) Pub. No.: US 2021/0242430 A1
(43) Pub. Date: Aug. 5, 2021

(54) DISPLAY PANEL, FABRICATING METHOD THEREOF, AND ELECTRONIC DEVICE

(71) Applicant: WUHAN CHINA STAR OPTOELECTRONICS TECHNOLOGY CO., LTD, Wuhan, Hubei (CN)

(72) Inventor: Yuejun TANG, Wuhan, Hubei (CN)

(21) Appl. No.: 16/303,669

(22) PCT Filed: Sep. 13, 2018
(86) PCT No.: PCT/CN2018/105552

§ 371 Date: Nov. 21, 2018

(30) Foreign Application Priority Data
Aug. 30, 2018 (CN) 201811001043.6

(51) Int. Cl. H01L 51/52; H01L 27/32; H01L 51/56

(52) U.S. Cl. CPC H01L 51/5271; H01L 27/322; H01L 51/56; H01L 51/5206; H01L 27/3248; H01L 2227/323; H01L 51/5234; H01L 2251/5315

(57) ABSTRACT

A display panel, a fabricating method thereof, and an electronic device are provided. The display panel includes an array substrate; a color resist layer located on the array substrate; a light-emitting device layer located on the color resist layer; and a reflecting layer located between the color resist layer and the array substrate The reflecting layer reflects light emitted by the light-emitting device layer.

### FIELD OF INVENTION

The present disclosure relates to a technical field of displays, and more particularly to a display panel, a fabricating method thereof, and an electronic device.

### BACKGROUND OF INVENTION

In flat panel display technologies, organic light-emitting diode (OLED) displays have advantages of being lightweight and slim, and having active light emission, fast response speed, large viewing angles, wide color gamuts, high brightness, low power consumption, etc., and have gradually become third generation display technologies after liquid crystal displays.

A color filter layer of existing white light OLED display panels is located between an insulating layer and a flat layer, and an anode layer, a light-emitting layer, and a cathode layer of a light-emitting device layer are located between the flat layer and a pixel definition layer. Based on the structure, existing white light OLED display panels are generally bottom emission type displays. That is, light emitted by the light-emitting layer is transmitted through a substrate to reach human eyes. Therefore, in order to maximize utilization of the light emitted by the light-emitting layer, the light-emitting layer confined by the pixel definition layer may only be disposed between thin Mm transistors (TFTs), and may not be disposed above the TFTs, which limits an aperture ratio or a size of an area of a light-emitting region in each pixel of existing white light OLED display panels.

Hence, it is desired to provide a display panel to solve the aforementioned problems.

### SUMMARY INVENTION

The present disclosure provides a display panel, a fabricating method thereof, and an electronic device, to solve the problem that existing OLED display panels have a smaller aperture ratio.

In order to solve the aforementioned problem, the present diclosure provides the following technical solutions.

In accordance with an embodiment of the present disclosure, a display panel includes:
an array substrate;
a color resist layer located on the array substrate;
a light-emitting device layer located on the color resist layer; and
a reflecting layer located between the color resist layer and the array substrate, wherein the reflecting layer reflects light emitted by the light-emitting device layer.

In the display panel in accordance with an embodiment of the present disclosure, the light-emitting device layer includes an anode layer, a light-emitting layer located on the anode layer, and a cathode layer located on the light-emitting layer. The anode layer is a transparent electrode, and the cathode layer is a transparent electrode or a semi-transparent electrode.

In the display panel in accordance with an embodiment of the present disclosure, the reflecting layer includes at least two reflecting units, and the reflecting units correspond one-to-one to light-emitting units in the light-emitting layer.

In the display panel in accordance with an embodiment of the present disclosure, an orthographic projection of the light-emitting layer on the reflecting layer is located within the reflecting layer.

In the display panel in accordance with an embodiment of the present disclosure, each of the reflecting units includes a first surface and a second surface, and the first surface is a concave surface away from the array substrate.

In accordance with an embodiment of the present disclosure, a fabricating method of a display panel includes:
providing an array substrate;
forming a color resist layer on the array substrate; and
forming a light-emitting device layer layer-by-layer on the color resist layer;
wherein before the color resist layer formed on the array substrate, the fabricating method further includes:
   forming a reflecting layer on the array substrate.

In the fabricating method in accordance with an embodiment of the present disclosure, the reflecting layer includes at least two reflecting units, and the reflecting units correspond one-to-one to light-emitting units in the light-emitting device layer.

In the fabricating method in accordance with an embodiment of the present disclosure, an orthographic projection of the light-emitting layer on the reflecting layer is located within the reflecting layer.

In the fabricating method in accordance with an embodiment of the present disclosure, each of the reflecting units includes a first surface and a second, surface, and the first surface is a concave surface away from the array substrate.

In accordance with an embodiment of the present disclosure, an electronic device includes a display panel. The display panel includes:
an array substrate;
a color resist layer located on the array substrate;
a light-emitting device layer located on the color resist layer, wherein the light-emitting device layer includes a light-emitting layer; and
a reflecting layer located between the color resist layer and the array substrate, wherein the reflecting layer reflects light emitted by the light-emitting device layer;
wherein the reflecting layer includes at least two reflecting units, and the reflecting units correspond one-to-one to light-emitting units in the light-emitting layer.

In the electronic device in accordance with an embodiment of the present disclosure, an orthographic projection of the light-emitting layer on the reflecting layer is located within the reflecting layer.

In the electronic device in accordance with an embodiment of the present disclosure, each of the reflecting units includes a first surface, and the first surface is a concave surface away from the array substrate.

Advantageous effects: The present disclosure, by disposing the reflecting layer between the color resist layer and the array substrate, provides a display panel forming a top-emission type white light display. A location limitation of an aperture region in a pixel is eliminated. An aperture ratio of the display panel is improved. An area of a light-emitting region is increased in addition, a portion of white light enters human eyes directly, enhancing luminous efficiency of the display panel, and lowering power consumption of the electronic device.

### DESCRIPTION OF DRAWINGS

In order to describe a technical solution in embodiments or existing technology more clearly, drawings required to be used by the embodiments or the existing technology are briefly introduced below. Obviously, the drawings in the description below are only some embodiments of the present disclosure. With respect to persons of ordinary skill in the art, under a premise that inventive efforts are not made, other drawings may be obtained based on these drawings.

FIG. 1 is a structural diagram of film layers of a display panel in accordance with a first embodiment of the present disclosure.

FIG. 2 is a structural diagram of film layers of a display panel in accordance with a second embodiment of the present disclosure.

FIG. 3 is a structural, diagram of film layers of a display panel in accordance with a third embodiment of the present disclosure.

FIG. 4 is a flowchart of a fabricating method of a display panel in accordance with an embodiment of the present disclosure.

FIG. 5 is a process diagram of the fabricating method of the display panel in accordance with an embodiment of the present disclosure.

FIG. 6 is another process diagram of the fabricating method of the display panel in accordance with the embodiment of the present disclosure.

### DETAILED DESCRIPTION OF PREFERRED EMBODIMENTS

The description of each embodiment below refers to respective accompanying drawing(s), so as to illustrate exemplarily specific embodiments of the present disclosure that may be practiced. Directional terms mentioned in the present disclosure, such as “upper”, “lower”, “front”, “back”, “left”, “right”, “inner”, “outer”, “side”, etc., are only directions by referring to the accompanying drawings, and thus the used directional terms are used to describe and understand the present disclosure, but the present disclosure is not limited thereto. In the drawings, structurally similar units are labeled by the same reference numerals.

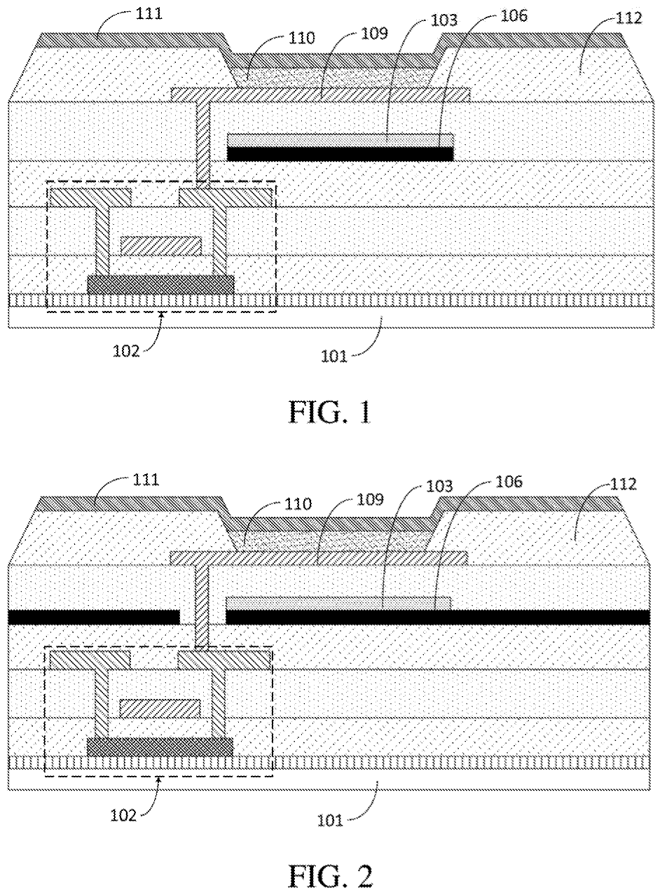

Referring to FIG. 1, FIG. 1 is a structural diagram of film layers of a display panel in accordance with a first embodiment of the present disclosure.

The display panel includes an array substrate, located on the array substrate, and a light-emitting device layer located on the color resist layer 103.

The array substrate includes a substrate 101 and a thin film transistor (TFT) layer 102 located on the substrate 101. In an embodiment, raw material of the substrate 101 may be one of a glass substrate, a quartz substrate, a resin substrate, and the like.

The TFT layer 102 includes an etch stop layer (ESL) type structure, a back channel etch (BCE) type structure, or a top-gate TFT type structure, and is not particularly limited. For example, the top-gate TFT type may include a buffer layer, an active layer, a gate insulating layer, a gate layer, an interlayer. insulating layer, a source/drain layer, and a flat layer.

The color resist layer 103 includes at least two color resist units. Any one of the color resist units includes one of a red color resist block, a green color resist block, and a blue color resist block. Each of the color resist units corresponds to one light-emitting unit in a light-emitting device.

The light-emitting device layer includes an anode layer 109, a light-emitting layer 110 located on the anode layer 109, and a cathode layer 111 located on the light-emitting layer 110.

The anode layer 109 is formed on the flat layer. The anode layer 109 includes at least two anodes arranged in an array. The anode layer 109 primarily provides holes for absorbing electrons.

The light-emitting layer 110 is formed on the anode layer 109. The light-emitting layer 110 is divided by a pixel definition layer 112 into a plurality of light-emitting units. Each of the light-emitting units corresponds to one of the anodes.

The cathode layer 111 is formed on the light-emitting device layer. The cathode layer 111 covers the light-emitting layer 110, and the pixel definition layer 112 located on the array substrate.

The display panel further includes a reflecting layer 106 located between the color resist layer 103 and the array substrate. The reflecting layer 106 reflects light emitted by the light-emitting device layer. Material of the reflecting layer 106 may be one selected from a group consisting of silver (Ag), aluminum (Al), chromium (Cr), molybdenum (Mo), tungsten (W), titanium (Ti), gold (Au), and palladium (Pd), and any composition thereof.

In an embodiment, because the display panel may be a top-emission type OLED display device, the anode layer 109 is a transparent metal electrode, and the cathode layer 111 is a transparent metal electrode or a semi-transparent metal electrode.

In an embodiment, material of the anode layer 109 may be at least one selected from a group consisting of indium tin oxide (ITO), indium zinc oxide (IZO), zinc oxide (ZnO), indium oxide (In2O3), indium gallium oxide (IGO), and zinc aluminum oxide (AZO). Material of the cathode layer 111 may be at least one selected from a group consisting of magnesium (Mg), calcium (Ca), aluminum (Al), and silver (Ag).

In an embodiment, light emitted by the light-emitting layer 110 is transmitted through the anode layer 109, and enters the color resist layer 103, and light corresponding to a color resist color is reflected, and is transmitted through the anode layer 109 and cathode layer 111 to enter human eyes.

In an embodiment, only a portion of light emitted by the light-emitting layer 110 is transmitted to the reflecting layer 106. Another portion of the light is directly transmitted through the cathode layer 111 to enter the human eyes. This portion of the light is white light not transmitted through a color filter film. Therefore, light emitted by each pixel unit is a superposition of white light and light filtered by a corresponding color resist, realizing an RGBW display.

Referring to FIG. 1, the reflecting layer 106 includes at least two reflecting units, and the reflecting units correspond one-to-one to the light-emitting units in the light-emitting layer 110. In an embodiment, an orthographic projection of the light-emitting layer 110 on the reflecting layer 106 is located within the reflecting layer 106.

Referring to FIG. 2, FIG. 2 is a structural diagram of film layers of a display panel in accordance with a second embodiment of the present disclosure.

The reflecting layer 106 occupies an entire layer on the array substrate. Because a via connecting the anode layer 109 and a source/drain has metal, the reflecting layer needs to be disposed such that the via is avoided, preventing short circuit of a circuit. Because a light source emitted by each of the light-emitting units is non-directional, by disposing the reflecting layer 106, luminous efficiency of a light-emitting device is enhanced.

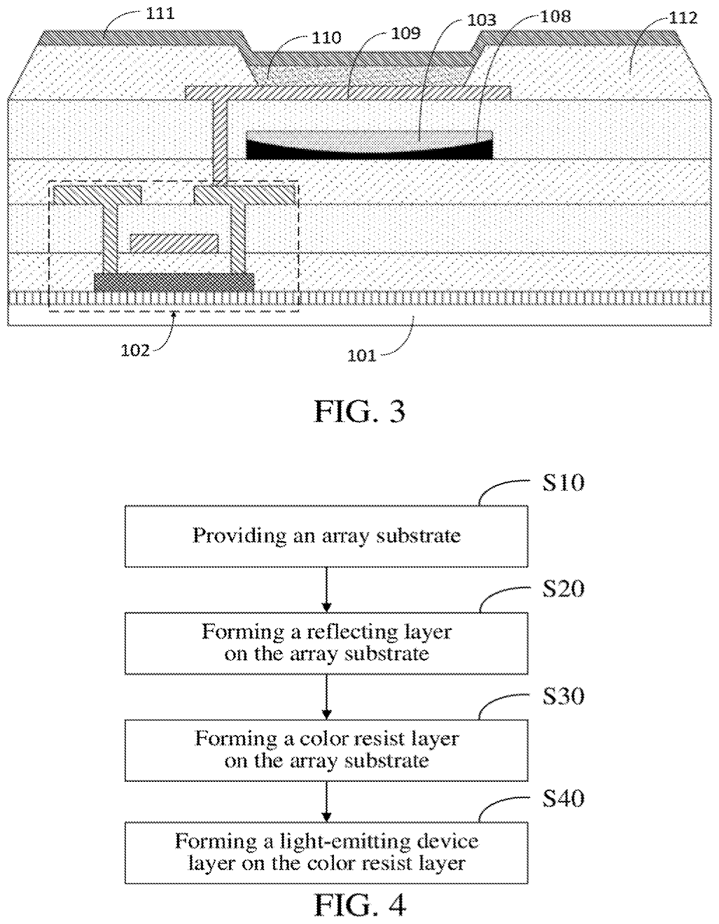

Referring to FIG. 3, FIG. 3 is a structural diagram of film layers of a display panel in accordance with a third embodiment of the present disclosure.

Each of the reflecting units 106 includes a first surface, and the first surface is a concave surface away from the array substrate. By the principle of a concave lens, the reflecting layer 106 is disposed as a recess, so that more proportion of emitted light perpendicularly passes through the cathode layer 111, enhancing luminous efficiency of a light-emitting device.

The present disclosure, by disposing the reflecting layer between the color resist layer and the array substrate, provides a display panel forming a top-emission type white light display. That is, color light passing through the color resist layer and white light not passing through the color resist layer are transmitted. A proportion of the white light to whole light may be adjusted by changing transmittance of the cathode layer, such as changing material or thickness of the cathode layer, thereby adjusting effects of the white light on a gain of ROB color brightness and color. The top-emission type white light display eliminates a location limitation of an aperture region in a pixel, improves an aperture ratio of the display panel, and increases an area of a light-emitting region. In addition, a portion of the white light enters human eyes directly, enhancing luminous efficiency of the display panel, and lowering power consumption of the electronic device.

Referring to FIG. 4, FIG. 4 is a flowchart of a fabricating method of a display panel in accordance with an embodiment of the present disclosure.

The fabricating method of the display panel includes the following steps.

In a step S10, an array substrate is provided.

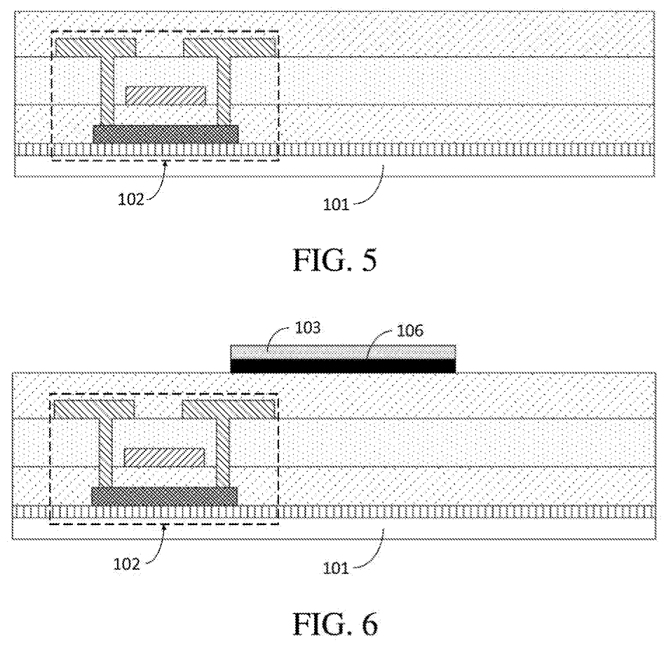

Referring to FIG. 5, FIG. 5 is a process diagram of the fabricating method of the display panel in accordance with an embodiment of the present disclosure.

In the present step, the provided array substrate includes a substrate 101 and a thin film transistor (TFT) layer 102 located on the substrate 101. In an embodiment, raw material of the substrate 101 may be one of a glass substrate, a quartz substrate, a resin substrate, and the like.

The TFT layer 102 includes an etch stop layer (ESL) type structure, a back channel etch (BCE) type structure, or a top-gate TFT type structure, and is not particularly limited. For example, the top-gate TFT type may include a buffer layer, an active layer, a gate insulating layer, a gate layer, an interlayer. insulating layer, a source/drain layer, and a flat layer.

In a step S20, a reflecting layer is formed on the array substrate

Referring to FIG. 6, FIG. 6 is another process diagram of the fabricating method of the display panel in accordance with the embodiment of the present disclosure.

In the present step, the reflecting layer 106 may be formed using a process such as deposition or metal sputtering, to form a structure illustrated in FIG. 1. The reflecting layer 106 reflects light emitted by the light-emitting device layer. In an embodiment, material of the reflecting layer 106 may be one selected from a group consisting of silver (Ag), aluminum (Al), chromium (Cr), molybdenum (Mo), tungsten (W), titanium (Ti), gold (Au), and palladium (Pd), and any composition thereof.

In a step S30, a color resist layer is formed on the array substrate.

In the present step, the color resist layer 103 may be prepared using a process such as a dyeing method, a printing method, an electrodeposition method, or an inkjet method.

The color resist layer 103 includes at least two color resist units. Any one of the color resist units includes one of a red color resist block, a green color resist block, and a blue color resist block. Each of the color resist units corresponds to one light-emitting unit in a light-emitting device.

In a step S40, a light-emitting device layer is formed layer-by-layer on the color resist layer.

In the present step, the light-emitting device layer includes an anode layer 109, a light-emitting layer 110 located on the anode layer 109, and a cathode layer 111 located on the light-emitting layer 110 to form the structure illustrated in FIG. 1.

The anode layer 109 is formed on the flat layer. The anode layer 109 includes at least two anodes arranged in an array. The anode layer 109 primarily provides holes for absorbing electrons.

The light-emitting layer 110 is formed on the anode layer 109. The light-emitting layer 110 is divided by a pixel definition layer 112 into a plurality of light-emitting units. Each of the light-emitting units corresponds to one of the anodes.

The cathode layer 111 is formed on the light-emitting device layer. The cathode layer 111 covers the light-emitting layer 110, and the pixel definition layer 112 located on the array substrate.

In an embodiment, because the display panel may be a top-emission type OLED display device, the anode layer 109 is a transparent metal electrode, and the cathode layer 111 is a transparent metal electrode or a semi-transparent metal electrode.

In an embodiment, material of the anode layer 109 may be at least one selected from a group consisting of indium tin oxide (ITO), indium zinc oxide (IZO), zinc oxide (ZnO), indium oxide (In2O3), indium gallium oxide (IGO), and zinc aluminum oxide (AZO). Material of the cathode layer 111 may be at least one selected from a group consisting of magnesium (Mg), calcium (Ca), aluminum (Al), and silver (Ag).

Referring to FIG. 1, the reflecting layer 106 includes at least two reflecting units, and the reflecting units correspond one-to-one to the light-emitting units in the light-emitting layer 110. In an embodiment, an orthographic projection of the light-emitting layer 110 on the reflecting layer 106 is located within the reflecting layer 106.

Referring to FIG. 2, the reflecting layer 106 occupies an entire layer on the array substrate. Because a via connecting the anode layer 109 and a source/drain has metal, the reflecting layer needs to be disposed such that the via is avoided, preventing short circuit of a circuit. Because a light source emitted by each of the light-emitting units is non-directional, by disposing the reflecting layer 106 luminous efficiency of a light-emitting device is enhanced.

Referring to FIG. 3, each of the reflecting units 106 includes a first surface, and the first surface is a concave surface away from the array substrate. By the principle of a concave lens, the reflecting layer 106 is disposed as a recess, so that more proportion of emitted light perpendicularly passes through the cathode layer 1 enhancing luminous efficiency of a light-emitting device.

In accordance with an embodiment of the present disclosure, an electronic device includes the aforementioned display panel. It can be understood that the electronic device includes but is not limited to a mobile phone, a tablet computer, a computer display, a game machine, a television, a display screen, a wearable device, and other living appliances or household appliances having a display function.

A display panel, a fabricating method thereof, and an electronic device are provided. The display panel includes an array substrate; a color resist layer located on the array substrate; a light-emitting device layer located on the color resist layer; and a reflecting layer located between the color resist layer and the array substrate. The reflecting layer reflects light emitted by the light-emitting device layer. The present disclosure, by disposing the reflecting layer between the color resist layer and the array substrate, provides a display panel forming a top-emission type white light display. A location limitation of an aperture region in a pixel is eliminated. An aperture ratio of the display panel is improved. An area of a light-emitting region is increased. In addition, a portion of white light enters human eyes directly, enhancing luminous efficiency of the display panel, and lowering power consumption of the electronic device.

In summary, although the present disclosure has been described with preferred embodiments thereof above, it is not intended to be limited by the foregoing preferred embodiments. Persons skilled in the art can carry out many changes and modifications to the described embodiments without departing from the scope and the spirit of the present disclosure. Therefore, the protection scope of the present disclosure is in accordance with the scope defined by the claims.

1. A display panel, comprising:
an array substrate;
a color resist layer located on the array substrate;
a light-emitting device layer located on the color resist layer; and
a reflecting layer located between the color resist layer and the array substrate, wherein the reflecting layer reflects light emitted by the light-emitting device layer.

2. The display panel of claim 1, wherein
the light-emitting device layer comprises an anode layer, a light-emitting layer located on the anode layer, and a cathode layer located on the light-emitting layer; and
the anode layer is a transparent electrode, and the cathode layer is a transparent electrode or a semi-transparent electrode.

3. The display panel of claim 2, wherein the reflecting layer comprises at least two reflecting units, and the reflecting units correspond one-to-one to light-emitting units in the light-emitting layer.

4. The display panel of claim 3, wherein an orthographic projection of the light-emitting layer on the reflecting layer is located within the reflecting layer.

5. The display panel of claim 3, wherein each of the reflecting units comprises a first surface, and the first surface is a concave surface away from the array substrate.

6. A fabricating method of a display panel, comprising:
providing an array substrate;
forming a color resist layer on the array substrate: and
forming a light-emitting device layer on the color resist layer;
wherein before the color resist layer is formed on the array substrate, the fabricating method further comprises:
forming a reflecting layer on the array substrate.

7. The fabricating method of claim 13, wherein the reflecting layer comprises at least two reflecting units, and the reflecting units correspond one-to-one to light-emitting units in the light-emitting device layer.

8. The fabricating method of claim 7, wherein an orthographic projection of the light-emitting layer on the reflecting layer is located within the reflecting layer.

9. The fabricating method of claim 7, wherein each of the reflecting units comprises a first surface, and the first surface is a concave surface away from the array substrate.

10. An electronic device, comprising a display panel, wherein the display panel comprises:
an array substrate;
a color resist layer located on the array substrate:
a light-emitting device layer located on the color resist layer, wherein the light-emitting device layer comprises a light-emitting layer; and
a reflecting, layer located between the color resist layer and the array substrate, wherein the reflecting layer reflects light emitted by the light-emitting device layer;
wherein the reflecting layer comprises at least two reflecting units, and the reflecting units correspond one-to-one to light-emitting units in the light-emitting layer.

11. The electronic device of claim 10, wherein an orthographic projection of the light-emitting layer on the reflecting layer is located within the reflecting layer.

12. The electronic device of claim 10, wherein each of the reflecting units comprises a first surface, and the first surface is a concave surface away from the array substrate.

13. The fabricating method of claim 6, wherein
the light-emitting device layer comprises an anode layer, a light-emitting layer located on the anode layer, and a cathode layer located on the light-emitting layer; and
the anode layer is a transparent electrode, and the cathode layer is a transparent electrode or a semi-transparent electrode.
